(19) United States
(12) Patent Application Publication
(10) Pub. No.: US 2006/0131683 A1
(43) Pub. Date: Jun. 22, 2006

(54) Microlens array

(75) Inventor: Ronald W. Wake, Hilton, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/075,679

(22) Filed: Mar. 9, 2005

Related U.S. Application Data
(63) Continuation-in-part of application No. 11/015,909, filed on Dec. 17, 2004.

(51) Int. Cl. H01L 31/0232

(52) U.S. Cl. 257/432; 359/619

(57) ABSTRACT

A microlens array includes two or more microlenses, wherein the individual microlenses are arranged and sized so that there are no gaps or substantially no gaps between microlenses through which incident light can pass without passing through a microlens.

### CROSS-REFERENCE TO RELATED APPLICATIONS

This is a continuation-in-part of application Ser. No. 11/015,909, filed Dec. 17, 2004, entitled “A Method For Producing A Microlens Array” by Ronald W. Wake.

### FIELD OF THE INVENTION

This invention relates to the fabrication of microlens arrays on the surface of electronic image sensors.

### BACKGROUND OF THE INVENTION

There continues to be a push to produce ever-higher resolution in electronic image sensors. This means the surface area of individual pixels is becoming smaller and thus the amount of light impinging on each pixel is also decreasing. Advances in the technology of the underlying electronic image sensor have helped boost the signal-to-noise ratio to compensate for the decreasing amount of light. However, since the photoactive part of a pixel is often only 50% or less of the total pixel area, the fabrication of microlens arrays aligned to the pixel arrays has proven to be a very effective way of increasing the fraction of incident light striking the photoactive area of the pixels.

A very efficient and manufacturable method of producing microlens arrays has been to form patterns in photoresist materials by standard microlithographic techniques. These patterns, which would have squared corners upon formation, are then melted and thus rounded into microlens features. A major requirement of this technique is that the individual microlenses need to be far enough apart so that when melted the adjacent patterns do not touch. If they were to touch the patterns would flow together and not produce the desired microlens shape. Thus, this technique always results in gaps between adjacent microlenses. These gaps would be around the periphery of the pixels and any light impinging on them would not be focused onto the photoactive area of the pixel. Thus there is a need for an effective method to produce microlens arrays where these gaps are reduced or eliminated.

Progress has been made in the reduction of these gaps by several methods. A common practice in the art of microlens array production is to first form the microlens shape in an upper layer using the flow technique described above. This microlens shape is then transferred into a lower layer by reactive ion etching (RIE). RIE is a plasma etching technique whereby the reactive ions of the plasma are accelerated towards the substrate by an electrical bias. This causes a very isotropic etch and an accurate transfer of the microlens shape into the underlying layer. This technique is used when the microlens material does not have the appropriate characteristics to allow direct microlithographic patterning and melting. U.S. Pat. No. 6,163,407, discloses this technique to reduce the final microlens gap. This is accomplished by altering the RIE conditions such that there is a mismatch in the etch rates of the two layers. This results in a slightly different microlens shape than the initial melted photoresist. Judicious adjustment of the etch rates can result in smaller gaps in the final microlens array. Although this method does result in reduced gaps, there isn't enough process latitude to completely eliminate the gaps around the entire perimeter of the pixel. Other disadvantages of this method include the need for the extra pattern transfer RIE step and the risk of damage to the underlying image sensor from the plasma environment.

Another method holding promise for the production of gapless microlens arrays is gray scale lithography. This method involves patterning the photoresist with a mask having a range of densities instead of the common 0% or 100%. The range of densities results in a range of solubilities of the exposed photoresist film. Thus the final photoresist profile after development matches the light intensity distribution transmitted by the mask. This method has several drawbacks however. First, as should be obvious, the design and production of the mask is quite complicated and expensive. Next, the photoresist must be able to accurately reproduce the varieties of light intensities. This is best accomplished with a photoresist having a contrast around 1. These types of photoresists are difficult to find since most photoresist development work has been aimed at the high contrast needed to produce the high-density circuits used in modern electronic devices. Also, these photoresists most likely do not contain the characteristics necessary for use as the final microlens material. These include transparency to visible light, stability to heat and light, and relatively high refractive index. This means that the photoresist pattern needs to be transferred into an underlying layer similarly to the method described previously. For these reasons gray scale lithography is not viewed as a manufacturable method of making gapless microlens arrays.

A conceptually simple method for forming gapless microlens arrays is to stamp the profile into a soft material using a rigid die. This technique goes by several different terms such as embossing, imprinting, and contact printing depending on the details of how it is applied. This type of technique is used to fabricate micro-optical components for fiber optics and display applications. The standard application involves a film of material coated on a substrate, which is subsequently stamped with the die. In most applications either heat or significant pressure is needed to imprint the die image into receiver layer. The application of this method to making microlens arrays for electronic image sensors is not likely since the use of pressure or heat causes distortions. These distortions are not of significant size to effect the quality of fiber optic or display devices however the pixel sizes are much smaller for image sensors and such distortions would severely effect performance.

Consequently, in view of the above, there is a need for a method to fabricate microlens arrays with reduced or eliminated gaps that is cost effective and produces microlens arrays having minimal distortions.

### SUMMARY OF THE INVENTION

The present invention relates to an improved method of forming microlens arrays on electronic image sensors. The improvement involves a method whereby adjacent microlenses can be packed close enough together to eliminate any significant gaps between them while allowing the use of a preferred spherical shape. The method involves the use of a template with the desired relief image for the microlens array. The imprint stamp is brought into contact with a polymerizable fluid composition such that the relief image is completely filled with said polymerizable fluid composition. The fluid nature of the polymerizable composition and capillary action allows this relief image filling to be accomplished with very little pressure. The imprint stamp is made of a material that is transparent to the wavelengths of light necessary to photochemically harden the polymerizable fluid composition. This allows irradiation through the imprint stamp while it is in contact with the polymerizable fluid composition. The result of this irradiation is a hardening of the polymerizable fluid composition. This hardening permits subsequent removal of the imprint stamp while the hardened polymerizable composition retains the desired microlens shape. The hardened polymerizable composition has the necessary optical transmission and stability properties that allow it to be used directly as the microlens array on electronic image sensors without having to transfer the microlens shape into an underlying layer by etching techniques.

### BRIEF DESCRIPTION OF THE DRAWINGS

FIG. 1 is a side view of an image sensor and a template used for creating microlenses spanning the image sensor which illustrates an initial step of the present invention in creating microlenses;

FIGS. 2-5 illustrate additional steps of the present invention used in creating microlenses spanning the image sensor;

FIG. 6 is a top view of the microlenses formed from the process illustrated in FIGS. 1-5;

FIG. 7 is a top view of microlenses that include overlapping portions created by an alternative template using the process of the present invention;

FIG. 8 a side view of an alternative template of the present invention;

FIG. 9 is a side view of the microlens array spanning the image sensor of the alternative embodiment; and

FIG. 10 is a top view of an alternative embodiment of the present invention.

### DETAILED DESCRIPTION OF THE INVENTION

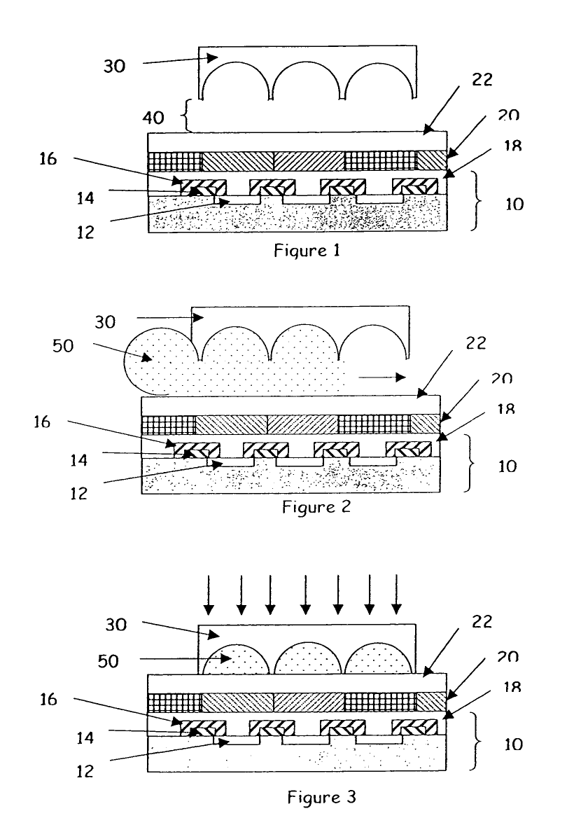

In a preferred embodiment of the present invention, illustrated in FIGS. 1-5, a method is provided by which a microlens array is formed on electronic image sensors. The method provides for adjacent microlenses packed close enough together to eliminate any significant gaps between them while allowing the use of a preferred spherical shape.

Referring to FIG. 1, a semiconductor portion 10, comprising photoactive areas 12, electrodes 14, and lightshields 16 is shown as representative of the typical elements of the semiconductor portion of a solid state electronic image sensor. For most applications of electronic image sensors, it is desirable to enhance the characteristics of the incoming electromagnetic radiation. In order to facilitate this enhancement, a planarization layer 18 is often applied to the surface of the semiconductor portion of the electronic image sensor. This planarization layer 18 can consist of a variety of materials the only requirements being that it does not adversely affect the spectral characteristics of the incoming radiation and is compatible with the materials and processes used in the manufacture of electronic image sensors. Since its purpose is planarization, there must be available a technique whereby the surface of the planarization layer 18 can be made planar with the surface of the photoactive areas 12 of the electronic image sensor. It is possible that simple spin coating would provide a sufficiently planar surface. However, other techniques such as plasma etch back and chemical mechanical planarization are commonly available to improve the co-planarity of the surface. Once a planar surface has been achieved, it may also be desirable to filter the spectral characteristics of the incoming radiation. This is accomplished by applying a color filter layer 20 consisting of two or more areas of different spectral transmission patterned so as to be aligned with the underlying photoactive areas 12. Since the photoactive areas 12 only comprise a portion of the total electronic image sensor there is a significant amount of incoming radiation that would fall on areas not able to capture it and produce an electronic signal. This leads to a reduction in the sensitivity of the electronic image sensor so it is often desirable to increase the fraction of the incoming radiation that falls on the photoactive areas 12. Fabricating a microlens array on top of the electronic image sensor whereby the individual microlens elements are aligned with the underlying photoactive areas 12 commonly does this. This microlens array requires both a planar surface and the correct distance from the surface of the photoactive area to accommodate the focal distance of the microlenses. These requirements often necessitate that application of a spacer layer 22 on top of the color filter layer 20. Since the spacer layer 22 serves only to physically position the microlens array, it has similar requirements to the planarization layer 18 and is often the same material. The present invention involves an improved method for forming the microlens array. The method involves the use of a template 30, which consists of a plurality of curved surfaces representing the desired relief image of the microlens array. As shown, the template 30 is aligned over the electronic imager sensor 10 with a gap 40.

Referring to FIG. 2, a photopolymerizable fluid composition 50 then contacts the surface of the spacer layer 22 and the template 30 so as to fill the gap 40 (shown in FIG. 1). The template 30 is made of a material, which is transparent to the photoactive wavelengths. A preferred material for fabricating the template 30 would be quartz, which is both transparent to a wide range of wavelengths and is dimensionally stable. The photopolymerizable fluid composition 50 may have a low viscosity such that it may fill the gap in an efficient manner. Preferably, the viscosity of the photopolymerizable fluid composition ranges from about 0.01 cps to about 100 cps measured at 25° C., and more preferably from about 0.01 cps to about 1 cps measured at this temperature.

Referring to FIG. 3, the template 30 is then moved closer to the spacer layer 22 to expel excess photopolymerizable fluid composition 50 such that the edges of the template 30 come into contact with the spacer layer 22. The photopolymerizable fluid composition 50 is then exposed to electromagnetic radiation of appropriate wavelength to polymerize the fluid.

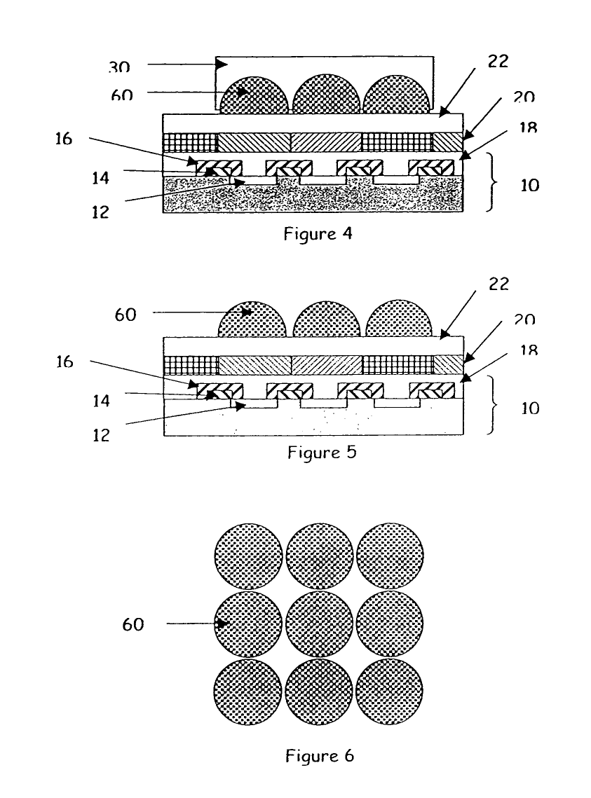

Now referring to FIG. 4, preferably, the photopolymerizable fluid composition 50 is exposed to radiation sufficient to polymerize the fluid composition and form a solidified polymeric material represented by 60. Preferably, the photopolymerizable fluid composition is exposed with ultra violet light, although other means of polymerizing the fluid composition are available such as heat or other forms of radiation.

The template 30 then leaves the solidified polymeric material 60 on the spacer layer 22, as shown in FIG. 5. The solidified polymeric material 60 is left in the desired microlens shape. Preferably, the solidified polymeric material 60 would have characteristics consistent with functioning as a microlens element (the combination of the microlens elements forms a microlens array) for electronic image sensors. These characteristics would include transparency to visible wavelengths that would not deteriorate with exposure to visible light or heat. Also, these characteristics include a Tg high enough so that the preferred microlens shape is preserved during any subsequent operations such as mounting the electronic image sensor in a suitable package.

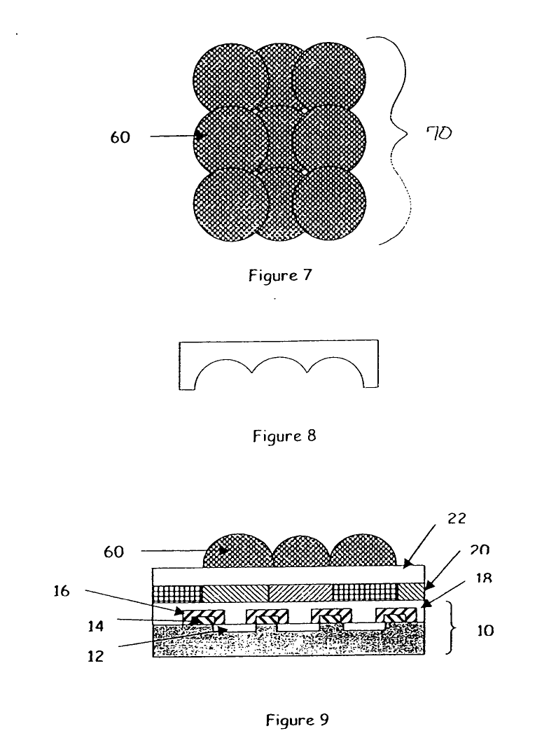

The microlens array depicted in FIG. 5 has the individual microlens array elements in close proximity to each other. In this lateral view it would seem that this is a very efficient arrangement. If, however, the overhead view of this same microlens array is examined, as shown in FIG. 6, it becomes obvious that a significant amount of open space is still present between diagonally adjacent microlens array elements. This type of microlens array is achievable in the prior art using the techniques described in the background. The present invention produces a similar microlens array using the process described above. Since it is advantageous to preserve a spherical shape for the microlenses in order to maximize the light focusing efficiency, increasing the diameter such that the diagonally adjacent microlens array elements come in contact or nearly so results in significant overlap of horizontally and vertically adjacent microlens array elements. This is depicted in an overhead view in FIG. 7. This close-packed arrangement of microlens array elements is not possible with the prior art technique involving the melting of photoresist patterns. This is because any contact of adjacent photoresist features during the melting will result in the features flowing together thus losing the desired microlens shape.

Referring to FIGS. 7, 8 and 9, the microlens array 70 shown in FIG. 7 is created by leaving the center of the individual microlens elements 60 in the same position over the photoactive areas 12, and expanding their diameter such that the gaps between diagonally adjacent microlenses reduce to essentially zero.

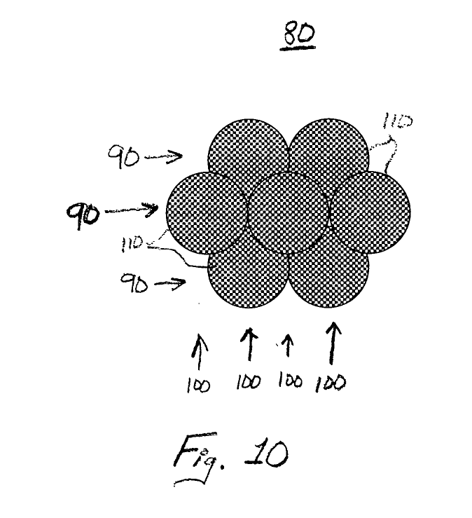

The only modification necessary to achieve the microlens array pattern shown in FIG. 7 is to change the layout of the microlens array elements in the template 30 (a template that does not create any gaps between adjacent microlenses or that creates some overlap in adjacent microlenses). FIG. 8 shows the lateral view of the template needed for this close-packed microlens array shown in FIG. 7. The processing steps shown in FIGS. 1-5 are followed the same way and result in the electronic image sensor shown in a lateral cross-section in FIG. 9.

Referring to FIG. 10, there is shown an alternative embodiment of the present invention. In this regard, the microlens array 80 includes a plurality of rows 90 and columns 100 of microlens array elements 110 in which each row 90 and column 100 includes a plurality of individual microlenses 110 of substantially the same size. Each row 90 is preferably offset from the adjacent row 90 by ½ of the pixel width. The columns 100 are arranged to preferably include microlenses 110 from every other row. In this manner, the individual microlenses 110 are arranged and sized so that there are no gaps or substantially no gaps between microlenses 110 through which incident light can pass without passing through a microlens 110.

The combination of size and arrangement are adjusted such that there are no gaps between any individual microlenses 110, as those skilled in the art can determine. In this manner the sizes of the individual microlenses 110 do not have to be the same, and the arrangement is adjusted according such that there are no gaps or substantially no gaps between individual microlenses. Again, the only modification necessary to achieve the microlens array pattern 80 shown in FIG. 10 is to change the layout of the microlens array elements in the template 30.

The invention has been described with reference to a preferred embodiment. However, it will be appreciated that variations and modifications can be effected by a person of ordinary skill in the art without departing from the scope of the invention.

### PARTS LIST

10 semiconductor portion/electronic imager sensor
12 photoactive areas
14 electrodes
16 lightshield
18 planarization layer
20 color filter array
22 spacer layer
30 template
40 gap
50 photopolymerizable fluid composition
60 solidified polymeric material
70 microlens array
80 alternative microlens array
90 rows
100 columns
110 individual microlenses

1. A microlens array comprising
a plurality of microlenses, wherein the individual microlenses are arranged and sized so that there are no gaps or substantially no gaps between microlenses through which incident light can pass without passing through a microlens.

2. The microlens array as in claim 1, wherein the individual microlenses are substantially and partially spherical including plano-convex and truncated spherical shapes.

3. The microlens array as in claim 1, wherein the individual microlenses are arranged in rows and columns, and the individual microlenses in the rows are sized such the individual microlenses in the rows partially overlap adjacent individual microlenses of the row, and the individual microlenses in the columns are sized such the individual microlenses in the columns of microlenses partially overlap adjacent individual microlenses of the column; and wherein diagonal separation between the microlenses is zero or substantially zero.

4. The microlens array as in claim 1, wherein the individual microlenses are arranged in a two-dimensional, predetermined pattern, and the individual microlenses in a row are sized such that the separation between the individual microlenses in the row is zero or substantially zero, and the individual microlenses in the row are offset by ½ pixel width from individual pixels in the adjacent row, wherein the individual microlenses are arranged and sized so that there are no gaps or substantially no gaps between microlenses through which incident light can pass without passing through a microlens.

5. The microlens array as in claim 3, wherein the individual microlenses are substantially and partially spherical including plano-convex and truncated spherical shapes.

6. The microlens array as in claim 4, wherein the individual microlenses are substantially and partially spherical including plano-convex and truncated spherical.

7. An image sensor comprising:
a microlens array comprising
a plurality of microlenses, wherein the individual microlenses are arranged and sized so that there are no gaps or substantially no gaps between microlenses through which incident light can pass without passing through a microlens.

8. The image sensor as in claim 7, wherein the individual microlenses are substantially and partially spherical including plano-convex and truncated spherical shapes.

9. The image sensor as in claim 7, wherein the individual microlenses are arranged in rows and columns, and the individual microlenses in the rows are sized such the individual microlenses in the rows partially overlap adjacent individual microlenses of the row, and the individual microlenses in the columns are sized such the individual microlenses in the columns of microlenses partially overlap adjacent individual microlenses of the column; and wherein diagonal separation between the microlenses is zero or substantially zero.

10. The microlens array as in claim 7, wherein the individual microlenses are arranged in a two-dimensional, predetermined pattern, and the individual microlenses in a row are sized such that the separation between the individual microlenses in the row is zero or substantially zero, and the individual microlenses in the row are offset by ½ pixel width from individual pixels in the adjacent row, wherein the individual microlenses are arranged and sized so that there are no gaps or substantially no gaps between microlenses through which incident light can pass without passing through a microlens.

11. The microlens array as in claim 9, wherein the individual microlenses are substantially and partially spherical including plano-convex and truncated spherical shapes.

12. The microlens array as in claim 10, wherein the individual microlenses are substantially and partially spherical including plano-convex and truncated spherical.

13. A camera comprising:
an image sensor comprising:
a microlens array comprising
a plurality of microlenses, wherein the individual microlenses are arranged and sized so that there are no gaps or substantially no gaps between microlenses through which incident light can pass without passing through a microlens.

14. The camera as in claim 13, wherein the individual microlenses are substantially and partially spherical including plano-convex and truncated spherical shapes.

15. The camera as in claim 13, wherein the individual microlenses are arranged in rows and columns, and the individual microlenses in the rows are sized such the individual microlenses in the rows partially overlap adjacent individual microlenses of the row, and the individual microlenses in the columns are sized such the individual microlenses in the columns of microlenses partially overlap adjacent individual microlenses of the column; and wherein diagonal separation between the microlenses is zero or substantially zero.

16. The camera as in claim 13, wherein the individual microlenses are arranged in a two-dimensional, predetermined pattern, and the individual microlenses in a row are sized such that the separation between the individual microlenses in the row is zero or substantially zero, and the individual microlenses in the row are offset by ½ pixel width from individual pixels in the adjacent row, wherein the individual microlenses are arranged and sized so that there are no gaps or substantially no gaps between microlenses through which incident light can pass without passing through a microlens.

17. The camera as in claim 15, wherein the individual microlenses are substantially and partially spherical including plano-convex and truncated spherical shapes.

18. The camera as in claim 16, wherein the individual microlenses are substantially and partially spherical including plano-convex and truncated spherical.
